(19) United States
(12) Patent Application Publication
(10) Pub. No.: US 2026/0255674 A1
(43) Pub. Date: Aug. 27, 2026

(54) DISPLAY DEVICE

(71) Applicant: Sharp Display Technology Corporation, Kameyama City, Mie (JP)

(72) Inventor: Tadayoshi MIYAMOTO, Kameyama City, Mie (JP)

(21) Appl. No.: 18/872,434

(22) PCT Filed: Aug. 4, 2022
(86) PCT No.: PCT/JP2022/029954

§ 371 Date: Dec. 6, 2024

(51) Int. Cl. H10D 86/40; H10D 86/60; H10K 59/121

(52) U.S. Cl. CPC H10D 86/423; H10D 86/60; H10K 59/1213

(57) ABSTRACT

A first TFT is included in a CMOS circuit provided to an output of a drive circuit so as to serve as a portion of the drive circuit. The first TFT includes: a plurality of first semiconductor layers provided to extend in parallel with one another; a first gate electrode provided to overlap with a first channel region of each of the first semiconductor layers through a first inorganic insulating film; a first source electrode electrically connected to a first source region of each first semiconductor layer; and a first drain electrode electrically connected to a first drain region of each first semiconductor layer.

### TECHNICAL FIELD

The present invention relates to a display device.

### BACKGROUND ART

In recent years, light-emitting organic electroluminescence (EL) display devices using organic EL elements have attracted attention as a replacement for liquid crystal display devices. An organic EL display device is provided with a plurality of thin-film transistors (hereinafter also referred to as “TFTs”) for each of subpixels. A subpixel is a minimum unit of an image. Here, examples of a well-known semiconductor layer constituting a TFT include: a semiconductor layer made of polysilicon having high mobility; and a semiconductor layer made of oxide semiconductor such as In—Ga—Zn—O and exhibiting low current leakage.

For example, Patent Document 1 discloses a display device having a hybrid structure in which a first TFT made of polysilicon semiconductor and a second TFT made of oxide semiconductor are formed on a substrate.

### CITATION LIST

### Patent Literature

[Patent Document 1] Japanese Unexamined Patent Application Publication No. 2020-017558

### SUMMARY OF INVENTION

### Technical Problems

A proposed organic EL display device having a hybrid structure includes, as a portion of a drive circuit, a complementary metal oxide semiconductor (hereinafter also referred to as “CMOS”) circuit that is a combination of a P-channel TFT formed of a polysilicon semiconductor and an N-channel TFT formed of an oxide semiconductor. Here, the organic EL display device has this CMOS circuit provided to the output of the drive circuit to which a high voltage is applied. Since the CMOS circuit outputs a large current, the N-channel TFT formed of an oxide semiconductor would have a wide channel width. However, if the N-channel TFT formed of an oxide semiconductor has a wide channel width or a short channel length, a drain current flows even if the N-channel TFT is in an OFF state, and the N-channel TFT is likely to deteriorate in characteristics. Hence, when the N-channel TFT, formed of an oxide semiconductor and included in the CMOS circuit provided to the output of the drive circuit, has a wide channel width, the N-channel TFT is likely to deteriorate in characteristics. Such a TFT has room for improvement.

The present invention is conceived in view of the above problems, and sets out to reduce deterioration in characteristics of an N-channel thin-film transistor formed of an oxide semiconductor and included in a complementary metal oxide semiconductor circuit provided to the output of a drive circuit.

### Solution to Problems

In order to achieve the above object, a display device according to the present invention includes: a base substrate; a thin-film transistor layer provided on the base substrate and including a first thin-film transistor and a second thin-film transistor, the first thin-film transistor having a first semiconductor layer formed of an oxide semiconductor and including a first channel region, a first source region, and a first drain region, and the second thin-film transistor having a second semiconductor layer formed of polysilicon; a display region that displays an image, and a picture-frame region defined around the display region; and a complementary metal oxide semiconductor circuit included in the picture-frame region and provided to an output of a drive circuit so as to serve as a portion of the drive circuit, the complementary metal oxide semiconductor circuit being a combination of the first thin-film transistor and the second thin-film transistor. The first thin-film transistor of the complementary metal oxide semiconductor circuit includes: a plurality of the first semiconductor layers provided to extend in parallel with one another; a first gate electrode provided to overlap with the first channel region of each of the first semiconductor layers through a first inorganic insulating film; a first source electrode electrically connected to the first source region of each first semiconductor layer; and a first drain electrode electrically connected to the first drain region of each first semiconductor layer.

### Advantageous Effects of Invention

The present invention can reduce deterioration in characteristics of an N-channel thin-film transistor formed of an oxide semiconductor and included in a complementary metal oxide semiconductor circuit provided to the output of a drive circuit.

### BRIEF DESCRIPTION OF DRAWINGS

FIG. 1 is a plan view of a schematic configuration of an organic EL display device according to a first embodiment of the present invention.

FIG. 2 is a plan view of a display region of the organic EL display device according to the first embodiment of the present invention.

FIG. 3 is a cross-sectional view of the display region of the organic EL display device according to the first embodiment of the present invention.

FIG. 4 is an equivalent circuit diagram of a TFT layer included in the organic EL display device according to the first embodiment of the present invention.

FIG. 5 is a cross-sectional view of an organic EL layer included in the organic EL display device according to the first embodiment of the present invention.

FIG. 6 is an equivalent circuit diagram of a drive circuit including a CMOS circuit of the organic EL display device according to the first embodiment of the present invention.

FIG. 7 is a cross-sectional view of the CMOS circuit included in the organic EL display device according to the first embodiment of the present invention.

FIG. 8 is a plan view of a first TFT included in the CMOS circuit of the organic EL display device according to the first embodiment of the present invention.

FIG. 9 is a plan view of a first TFT included in a CMOS circuit of an organic EL display device according to a second embodiment of the present invention.

FIG. 10 is a plan view of a modification of the first TFT included in the CMOS circuit of the organic EL display device according to the second embodiment of the present invention.

FIG. 11 is a plan view of a first TFT included in a CMOS circuit of an organic EL display device according to a third embodiment of the present invention.

### DESCRIPTION OF EMBODIMENTS

Embodiments of the present invention will be described in detail below with reference to the drawings. Note that the present invention shall not be limited to the embodiments below.

### First Embodiment

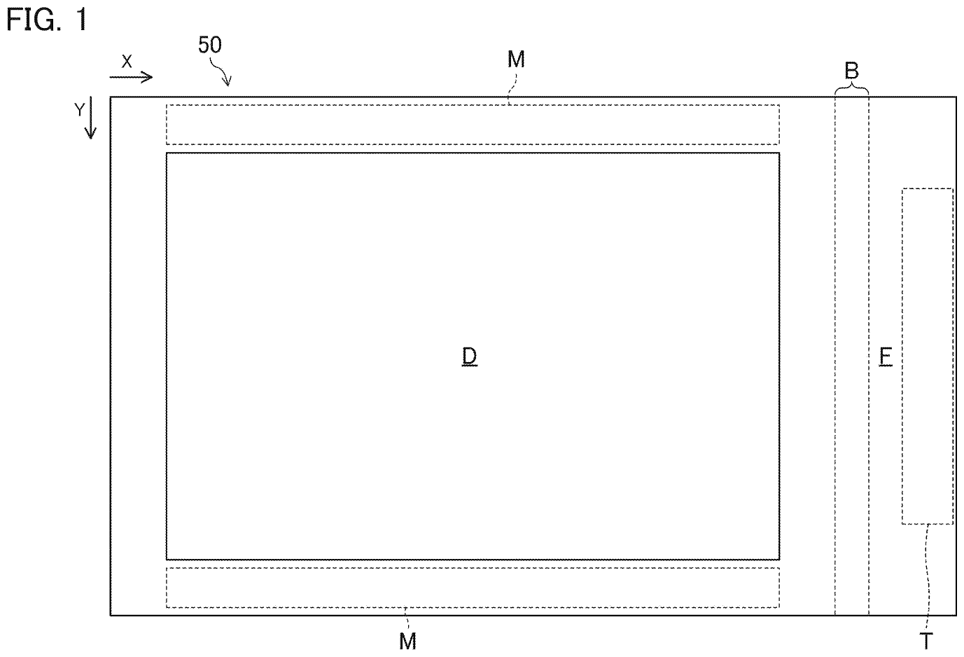

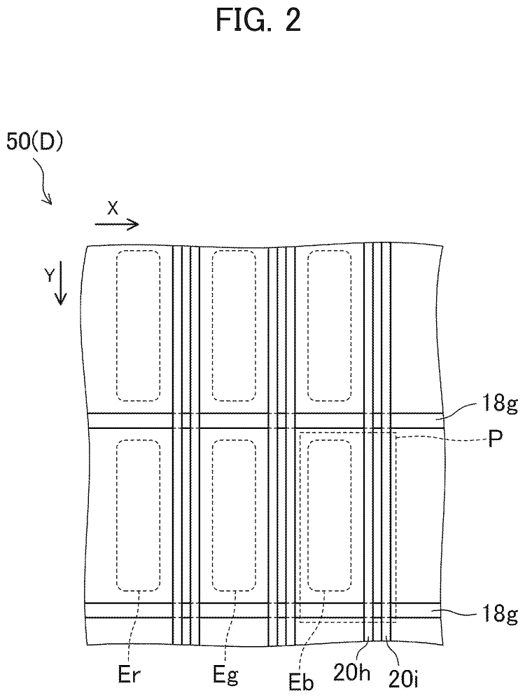

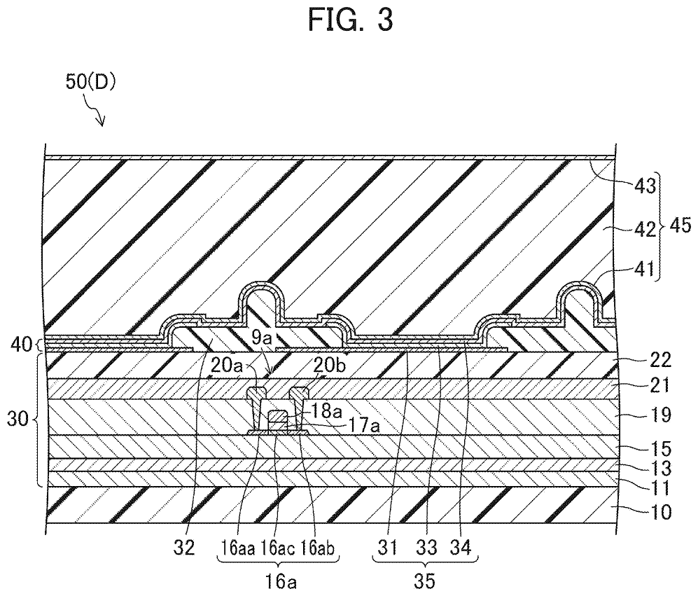

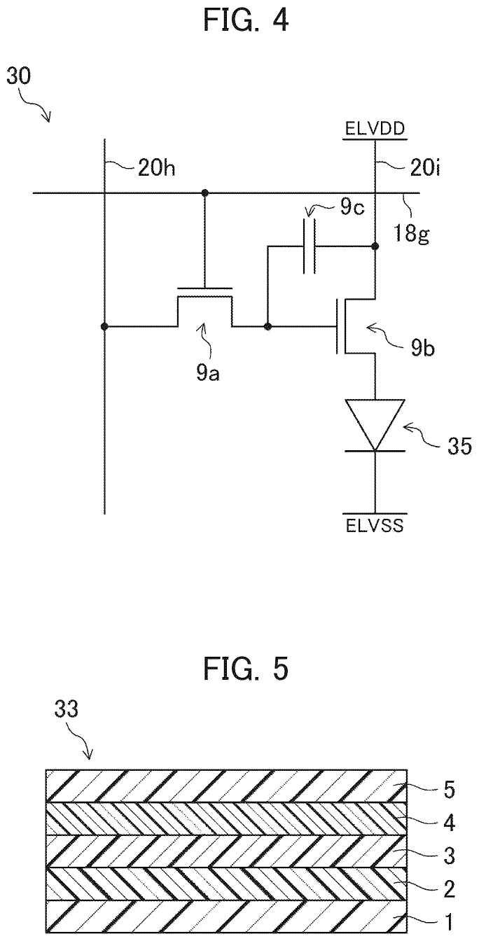

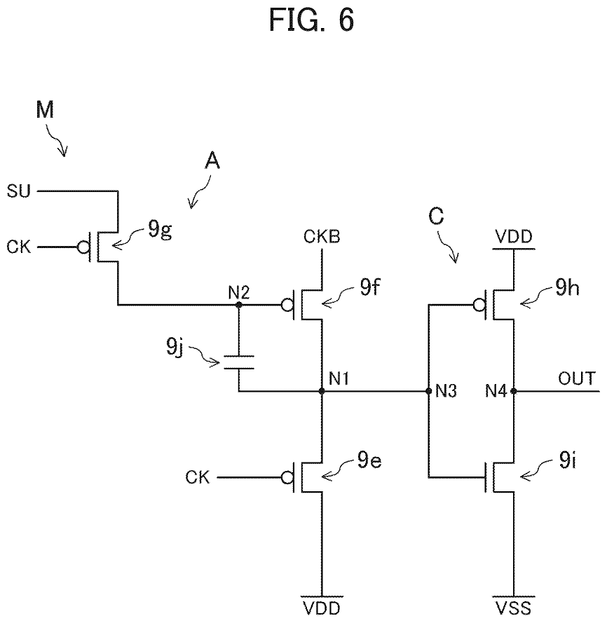

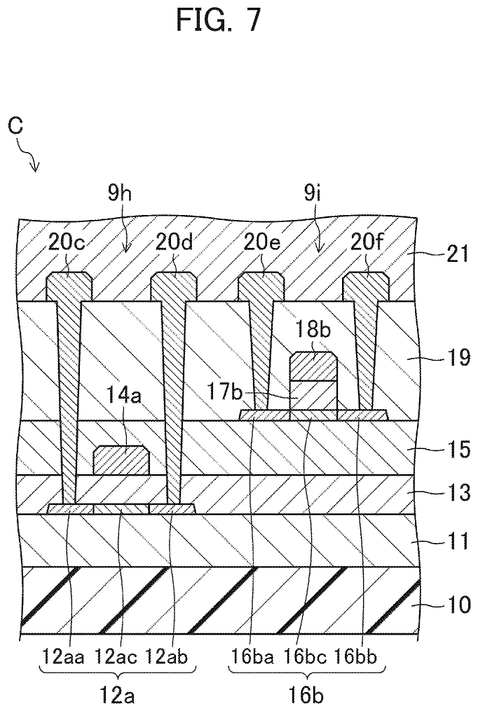

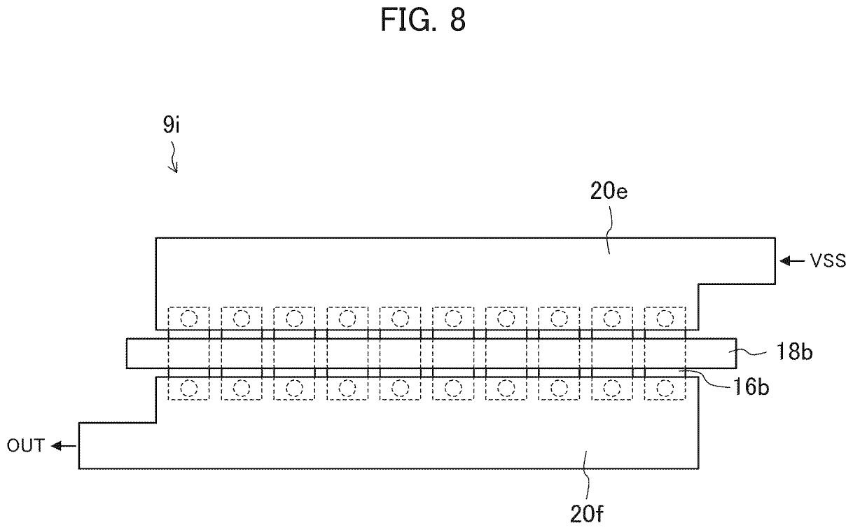

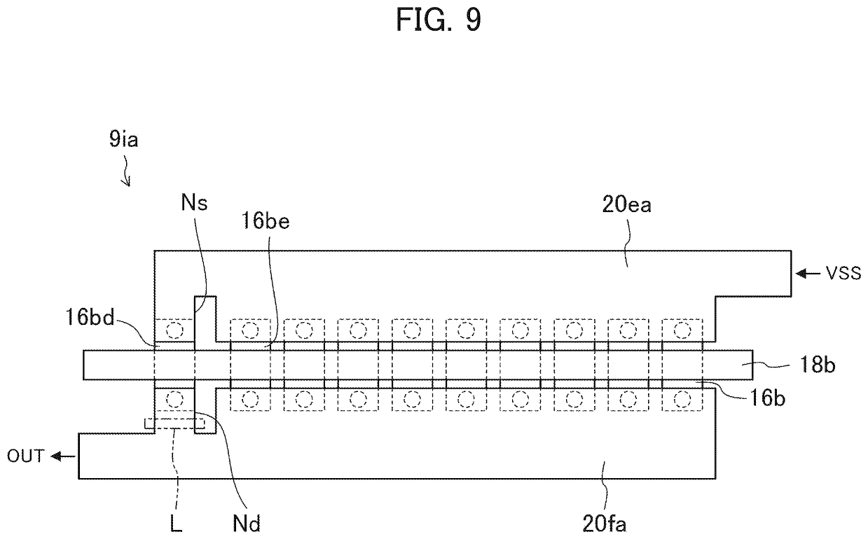

FIGS. 1 to 8 illustrate a first embodiment of a display device according to the present invention. Note that, in the embodiments below, an organic EL display device including an organic-EL-element layer is exemplified as a display device including a light-emitting-element layer. Here, FIG. 1 is a plan view of a schematic configuration of an organic EL display device 50 according to this embodiment. FIG. 2 and FIG. 3 are respectively a plan view and a cross-sectional view of a display region D of the organic EL display device 50. FIG. 4 is an equivalent circuit diagram of a TFT 30 included in the organic EL display device 50. FIG. 5 is a cross-sectional view of an organic EL layer 33 included in the organic EL display device 50. FIG. 6 is an equivalent circuit diagram of a gate driver circuit M including a CMOS circuit C of the organic EL display device 50. FIG. 7 is a cross-sectional view of the CMOS circuit C. FIG. 8 is a plan view of a fifth peripheral TFT 9i included in the CMOS circuit C.

As illustrated in FIG. 1, the organic EL display device 50 includes, for example: the display region D shaped into a rectangle and displaying an image; and a picture-frame region F shaped into a picture-frame shape and provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides.

The display region D illustrated in FIG. 2 includes a plurality of subpixels P arranged in a matrix. Moreover, in the display region D, as illustrated in FIG. 2, for example, subpixels P having red light-emitting regions Er for presenting red, subpixels P having green light-emitting regions Eg for presenting green, and subpixels P having blue light-emitting regions Eb for presenting blue are provided side by side. Note that, in the display region D, for example, neighboring three subpixels P each having one of a red light-emitting region Er, a green light-emitting region Eg, and a blue light-emitting region Eb constitute one pixel.

The picture-frame region F in FIG. 1 has a right end portion provided with a terminal unit T extending in one direction (in a Y-direction in the drawing). Moreover, as illustrated in FIG. 1, the picture-frame region F includes, for example, a folding portion B between the display region D and the terminal unit T. The folding portion B, provided to the terminal unit T toward the display region D and extending in one direction (in the Y-direction in the drawing), is foldable around a folding axis in the Y-direction in the drawing at an angle of 180° (foldable in a U-shape). Furthermore, the picture-frame region F in FIG. 1 has an upper end portion and a lower end portion each provided with a gate driver circuit M to serve as a drive circuit. Note that, as will described later, a CMOS circuit C is included in the picture-frame region F and provided to an output of the gate driver circuit M so as to serve as a portion of the gate driver circuit M. The CMOS circuit C is a combination of the fourth peripheral TFT 9h and the fifth peripheral TFT 9i.

As illustrated in FIG. 3, the organic EL display device 50 includes: a resin substrate 10 provided as a base substrate; a TFT layer 30 provided on the resin substrate 10; an organic-EL-element layer 40 provided on the TFT layer 30 and to serve as a light-emitting-element layer; and a sealing film 45 provided on the organic-EL-element layer 40.

The resin substrate 10 is made of, for example, such a material as polyimide resin.

As illustrated in FIG. 3, the TFT layer 30 includes: a base coat film 11 provided on the resin substrate 10; a plurality of first pixel TFTs 9a and a plurality of second pixel TFTs 9b (see FIG. 4) provided on the base coat film 11 to serve as N-channel first TFTs; a plurality of capacitors 9c (see FIG. 4) provided on the base coat film 11; and a protective insulating film 21 and a planarization film 22 sequentially provided above each of the first pixel TFTs 9a, each of the second pixel TFTs 9b, and each of the capacitors 9c. Here, the TFT layer 30 includes, as illustrated in FIG. 2, a plurality of gate lines 18g extending in parallel with one another in an X-direction in the drawing. Furthermore, the TFT layer 30 includes, as illustrated in FIG. 2, a plurality of source lines 20h extending in a direction intersecting with (perpendicular to) the plurality of gate lines 18g; that is, extending in parallel with one another in the Y-direction in the drawing. Moreover, the TFT layer 30 includes, as illustrated in FIG. 2, a plurality of power supply lines 20i extending in parallel with one another in the Y-direction in the drawing. Thus, as illustrated in FIG. 2, the power supply lines 20i and the source lines 20h are provided side by side. Furthermore, in the TFT layer 30, as illustrated in FIG. 4, each subpixel P includes: a first pixel TFT 9a; a second pixel TFT 9b; and a capacitor 9c. Note that, as illustrated in FIG. 3, the TFT layer 30 includes: the base coat film 11; a second semiconductor film to serve as a second semiconductor layer 12a to be described later; a first gate insulating film 13 provided as a second inorganic insulating film; a first metal film to serve as, for example, a second gate electrode 14a to be described later; a first interlayer insulating film 15 provided as a third inorganic insulating film; a first semiconductor film to serve as, for example, a first semiconductor layer 16a to be described later; second gate insulating films 17a and 17b provided as first inorganic insulating films; a second metal film to serve as, for example, a gate line 18g; a second interlayer insulating film 19 provided as a fourth inorganic insulating film; a third metal film to serve as, for example, a source line 20h and a power supply line 20i; the protective insulating film 21; and the planarization film 22, all of which are sequentially stacked on top of another above the resin substrate 10.

Each of the base coat film 11, the first gate insulating film 13, the first interlayer insulating film 15, the second gate insulating films 17a and 17b, the second interlayer insulating film 19, and the protective insulating film 21 is a monolayer inorganic insulating film made of such a substance as, for example, silicon nitride, silicon oxide, or silicon oxynitride. Alternatively, each film is a multilayer inorganic insulating film made of these substances. Here, for example, a silicon oxide film is included: in the first interlayer insulating film 15 at least toward the first semiconductor layers 16a and 16b; in the second gate insulating film 17a at least toward the first semiconductor layer 16a; and in the second gate insulating film 17b at least toward the first semiconductor layer 16b.

As illustrated in FIG. 4, in each subpixel P, the first pixel TFT 9a is electrically connected to the corresponding gate line 18g and source line 20h. Furthermore, as illustrated in FIG. 3, the first pixel TFT 9a includes: the first semiconductor layer 16a provided on the first interlayer insulating film 15; a gate electrode 18a provided above the first semiconductor layer 16a through the second gate insulating film 17a; and a source electrode 20a and a drain electrode 20b provided on the second interlayer insulating film 19 and spaced apart from each other.

The first semiconductor layer 16a is the first semiconductor film formed of, for example, an In—Ga—Zn—O-based oxide semiconductor. As illustrated in FIG. 3, the first semiconductor layer 16a includes: a first source region 16aa and a first drain region 16ab defined to be spaced apart from each other; and a first channel region 16ac defined between the first source region 16aa and the first drain region 16ab. Here, the In—Ga—Zn—O-based semiconductor is a ternary oxide of indium (In), gallium (Ga), and zinc (Zn), and a ratio (a composition ratio) of In to Ga to Zn shall not be limited to a particular ratio. Furthermore, the In—Ga—Zn—O-based semiconductor may be amorphous or crystalline. Note that the crystalline In—Ga—Zn—O-based semiconductor is preferably a crystalline In—Ga—Zn—O-based semiconductor in which the c-axis is oriented substantially perpendicular to the layer plane. Moreover, instead of the In—Ga—Zn—O-based semiconductor, the first semiconductor layer 16a may contain another oxide semiconductor. Examples of the other oxide semiconductor may include an In-Sn-Zn-O-based semiconductor (e.g., In₂O₃—SnO₂—ZnO; InSnZnO). Here, the In—Sn—Zn—O-based semiconductor is a ternary oxide of indium (In), tin (Sn), and zinc (Zn). In addition, other oxide semiconductors may include: an In—Al—Zn—O-based semiconductor; an In—Al—Sn—Zn—O-based semiconductor; a Zn—O-based semiconductor; an In—Al—Zn—O-based semiconductor; a Zn—Ti—O-based semiconductor; a Cd—Ge—O-based semiconductor; a Cd—Pb—O-based semiconductor; cadmium oxide (CdO); a Mg—Zn—O-based semiconductor; an In—Ga—Sn—O-based semiconductor; an In—Ga—Sn—O-based semiconductor; a Zr—In—Zn—O-based semiconductor; a Hf—In—Zn-O-based semiconductor; an Al—Ga—Zn—O-based semiconductor; a Ga—Zn—O-based semiconductor; an In—Ga—Sn—Zn—Sn—O-based semiconductor; InGaO₃(ZnO)₅; zinc magnesium oxide (MgₓZn₁₋ₓO), and zinc cadmium oxide (CdₓZn₁₋ₓO). Note that the Zn—O-based semiconductor may be ZnO doped with one or more kinds of impurity elements among a group 1 element, a group 13 element, a group 14 element, a group 15 element, and a group 17 element. The Zn—O-based semiconductor may be in an amorphous state, in a polycrystalline state, or in a microcrystalline state in which an amorphous state and a polycrystalline state are mixed together. Alternatively. the Zn—O-based semiconductor does not have to be doped with any impurity element.

As illustrated in FIG. 3, the gate electrode 18a is provided to overlap with the first channel region 16ac of the first semiconductor layer 16a. The gate electrode 18a controls conduction between the first source region 16aa and the first drain region 16ab of the first semiconductor layer 16a. Furthermore, similar to the gate line 18g, the gate electrode 18a is formed of the second metal film.

As illustrated in FIG. 3, the source electrode 20a and the drain electrode 20b are respectively and electrically connected to the first source region 16aa and the first drain region 16ab of the first semiconductor layer 16a through respective contact holes formed in the second interlayer insulating film 19. Moreover, similar to the source line 20h and the power supply line 20i, the source electrode 20a and the drain electrode 20b are formed of the third metal film.

As illustrated in FIG. 4, in each subpixel P, the second pixel TFT 9b is electrically connected to the corresponding first pixel TFT 9a and power supply line 20i. In addition, similar to the first pixel TFT 9a described above, the second pixel TFT 9b includes: the first semiconductor layer 16a; the gate electrode 18a; the source electrode 20a; and the drain electrode 20b.

As illustrated in FIG. 4, in each subpixel P, the capacitor 9c is electrically connected to the corresponding first pixel TFT 9a and power supply line 20i. Here, the capacitor 9c includes, for example: a lower conductive layer formed of the second metal film; an upper conductive layer formed of the third metal film; and the second interlayer insulating film 19 provided between the lower conductive layer and the upper conductive layer. Note that the upper conductive layer is electrically connected to the power supply line 20i through a contact hole formed in the second interlayer insulating film 19.

The planarization film 22 has a flat surface in the display region D. The planarization film 22 is made of, for example, an organic resin material such as polyimide resin.

As illustrated in FIG. 3, the organic-EL-element layer 40 includes a plurality of organic EL elements 35. The organic EL elements 35, serving as a plurality of light-emitting elements, are arranged on the TFT layer 30 in a matrix, so as to correspond to the plurality of respective subpixels P. Here, as illustrated in FIG. 3, each of the organic EL elements 35 includes: a first electrode 31 provided on the TFT layer 30; an organic EL layer 33 provided on the first electrode 31; and a second electrode 34 provided on the organic EL layer 33 in common with the entire display region D.

The first electrode 31 is electrically connected to the drain electrode 20b of the second pixel TFT 9b for each subpixel P, through a contact hole formed in the protective insulating film 21 and the planarization film 22. Furthermore, the first electrode 31 has a function of injecting holes into the organic EL layer 33. Moreover, the first electrode 31 is preferably formed of a material having a large work function to improve efficiency in injecting the holes into the organic EL layer 33. Here, examples of the material forming the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, the first electrode 31 may be made of, for example, an alloy of astatine (At)/astatine oxide (AtO₂). Furthermore, the first electrode 31 may be made of a conductive oxide such as, for example, tin oxide (SnO), zinc oxide (ZnO), indium tin oxide (ITO), or indium zinc oxide (IZO). Moreover, the first electrode 31 may be formed of a plurality of layers made of the above materials and stacked on top of another. Note that examples of compound materials having a large work function include indium tin oxide (ITO) and indium zinc oxide (IZO). In addition, the first electrode 31 has a peripheral end portion covered with an edge cover 32 provided in a grid pattern throughout the display region D. Here, the edge cover 32 is made of, for example, an organic resin material such as polyimide resin or acrylic resin, or a polysiloxane-based spin-on-glass (SOG) material.

As illustrated in FIG. 5, the organic EL layer 33 includes: a hole injection layer 1; a hole transport layer 2; a light-emitting layer 3; an electron transport layer 4; and an electron injection layer 5, all of which are sequentially stacked above the first electrode 31.

The hole injection layer 1 is also referred to as an anode buffer layer. The hole injection layer 1 has a function of approximating energy levels between the first electrode 31 and the organic EL layer 33 to improve efficiency in injecting the holes from the first electrode 31 into the organic EL layer 33. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 31 to the organic EL layer 33. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the first electrode 31 and the second electrode 34, and recombine together, when a voltage is applied with the first electrode 31 and the second electrode 34. Here, the light-emitting layer 3 is formed of a material having high light-emission efficiency. Examples of the material forming the light-emitting layer 3 include a metal oxinoid compound[8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 34 and the organic EL layer 33 to improve efficiency in injecting the electrons from the second electrode 34 into the organic EL layer 33. Such a function can decrease a drive voltage of the organic EL element 35. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 34 is provided to cover each organic EL layer 33 and the edge cover 32. Moreover, the second electrode 34 has a function of injecting the electrons into the organic EL layer 33. Furthermore, the second electrode 34 is preferably formed of a material having a small work function to improve efficiency in injecting the electrons into the organic EL layer 33. Here, examples of the material forming the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 34 may be formed of a conductive oxide such as tin oxide (SnO), zinc oxide (ZnO), indium tin oxide (ITO), or indium zinc oxide (IZO). In addition, the second electrode 34 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 45 is provided to cover the second electrode 34, and includes: a first inorganic sealing film 41; an organic sealing film 42; and a second inorganic sealing film 43, all of which are sequentially stacked on top of another above the second electrode 34. The sealing film 45 has a function of protecting the organic EL layers 33 in the organic EL element 35 from moisture and oxygen. Here, each of the first inorganic sealing film 41 and the second inorganic sealing film 43 is formed of such an inorganic insulating film as, for example, a silicon nitride film, a silicon oxide film, or a silicon oxynitride film. Moreover, the organic sealing film 42 is formed of such an organic resin material as, for example, acrylic resin, epoxy resin, silicone resin, polyurea resin, parylene resin, polyimide resin, or polyamide resin.

Furthermore, the organic EL display device 50 (the TFT layer 30) includes the gate driver circuit M in the picture-frame region F. As illustrated in FIG. 6, the gate driver circuit M includes: a flip-flop circuit A; and the CMOS circuit C, both of which are provided for each gate line 18g.

The flip-flop circuit A illustrated in FIG. 6 includes: a first peripheral TFT 9e, a second peripheral TFT 9f, and a third peripheral TFT 9g provided as P-channel second TFTs; and a capacitor 9j. The flip-flop circuit A alternately receives a clock signal CK and an inverted clock signal CKB to output, to a node N1, a gate signal shifted by a half cycle from the clock signal CK.

Similar to the fourth peripheral TFT 9h to be described later, each of the first peripheral TFT 9e, the second peripheral TFT 9f, and the third peripheral TFT 9g includes: the second semiconductor layer 12a; the second gate electrode 14a; a second source electrode 20c; and a second drain electrode 20d.

The first peripheral TFT 9e illustrated in FIG. 6 has: a gate electrode (the second gate electrode 14a) receiving the clock signal CK; a source electrode (the second source electrode 20c) electrically connected to a power supply line of a high level VDD; and a drain electrode (the second drain electrode 20d) electrically connected to the node N1.

The second peripheral TFT 9f illustrated in FIG. 6 has: a gate electrode (the second gate electrode 14a) electrically connected to a node N2; a source electrode (the second source electrode 20c) receiving the inverted clock signal CKB; and a drain electrode (the second drain electrode 20d) electrically connected to the node N1.

The third peripheral TFT 9g illustrated in FIG. 6 has: a gate electrode (the second gate electrode 14a) receiving the clock signal CK; a source electrode (the second source electrode 20c) receiving a start pulse SU; and a drain electrode (the second drain electrode 20d) electrically connected to the node N2. Here, the start pulse SU is applied when the flip-flop circuit A is in the first stage. When the flip-flop circuit A is in the second stage succeeding the first state, the source electrode of the third peripheral TFT 9g receives the gate signal output in the first stage, instead of the start pulse SU. Hence, in a stage succeeding the second stage, the source electrode (the second source electrode 20c) of the third peripheral TFT 9g of the flip-flop circuit A receives a gate signal of the preceding stage.

The capacitor 9j illustrated in FIG. 6 is connected between the node N1 and the node N2, and maintains a voltage between the second drain electrode 20d and the second gate electrode 14a in the second peripheral TFT 9f.

The CMOS circuit C illustrated in FIGS. 6 and 7 includes: a fourth peripheral TFT 9h provided as a P-channel second TFT; and a fifth peripheral TFT 9i provided as an N-channel first TFT. If the gate signal input from a node N3 has the same potential as that of a low-level voltage VSS, the fourth peripheral TFT 9h turns ON, the fifth peripheral TFT 9i turns OFF, and the same potential as a high-level voltage VDD is output from a node N4. If the gate signal input from the node N3 has the same potential as that of the high-level voltage VDD, the fourth peripheral TFT 9h turns OFF, the fifth peripheral TFT 9i turns ON, and the same potential as the low-level voltage VSS is output from the node N4. Note that the node N3 of the CMOS circuit C is electrically connected to the node N1 of the flip-flop circuit A.

The fourth peripheral TFT 9h illustrated in FIG. 6 has: a gate electrode (the second gate electrode 14a) electrically connected to the node N3; a source electrode (the second source electrode 20c) electrically connected to a power supply line of the high-level voltage VDD; and a drain electrode (the second drain electrode 20d) electrically connected to the node N4. Furthermore, as illustrated in FIG. 7, the fourth peripheral TFT 9h includes: the second semiconductor layer 12a provided on the base coat film 11; the second gate electrode 14a provided above the second semiconductor layer 12a through the first gate insulating film 13; and the second source electrode 20c and the second drain electrode 20d provided on the second interlayer insulating film 19 and spaced apart from each other.

The second semiconductor layer 12a is the second semiconductor film formed of, for example, polysilicon such as low-temperature polysilicon (LTPS). As illustrated in FIG. 7, the second semiconductor layer 12a includes: a second source region 12aa and a second drain region 12ab defined to be spaced apart from each other; and a second channel region 12ac defined between the second source region 12aa and the second drain region 12ab.

As illustrated in FIG. 7, the second gate electrode 14a is provided to overlap with the second channel region 12ac of the second semiconductor layer 12a. The second gate electrode 14a controls conduction between the second source region 12aa and the second drain region 12ab of the second semiconductor layer 12a. Furthermore, as described above, the second gate electrode 14a is formed of the first metal film.

As illustrated in FIG. 7, the second source electrode 20c and the second drain electrode 20d are respectively and electrically connected to the second source region 12aa and the second drain region 12ab of the second semiconductor layer 12a through respective contact holes formed in the first gate insulating film 13, the first interlayer insulating film 15, and the second interlayer insulating film 19. Moreover, similar to the source line 20h and the power supply line 20i, the second source electrode 20c and the second drain electrode 20d are formed of the third metal film.

The fifth peripheral TFT 9i illustrated in FIG. 6 has: a gate electrode (a first gate electrode 18b) electrically connected to the node N3; a source electrode (a first source electrode 20e) electrically connected to a power supply line of the low-level voltage VSS; and a drain electrode (a first drain electrode 20f) electrically connected to the node N4. Furthermore, as illustrated in FIGS. 7 and 8, the fifth peripheral TFT 9i includes: a plurality of the first semiconductor layers 16b provided on the first interlayer insulating film 15 to extend in parallel with one another; the first gate electrode 18b provided above each of the first semiconductor layers 16b through the second gate insulating film 17b; and the first source electrode 20e and the first drain electrode 20f provided on the second interlayer insulating film 19 and spaced apart from each other.

Similar to the first semiconductor layer 16a, the first semiconductor layer 16b is the second semiconductor film formed of, for example, an In—Ga—Zn—O-based oxide semiconductor. As illustrated in FIG. 7, the first semiconductor layer 16b includes: a first source region 16ba and a first drain region 16bb defined to be spaced apart from each other; and a first channel region 16bc defined between the first source region 16ba and the first drain region 16bb.

As illustrated in FIG. 7, the first gate electrode 18b is provided to overlap with the first channel region 16bc of each of the first semiconductor layers 16b. The first gate electrode 18b controls conduction between the first source region 16ba and the first drain region 16bb of the first semiconductor layer 16b. Furthermore, similar to the gate line 18g, the first gate electrode 18b is formed of the second metal film.

As illustrated in FIG. 7, the first source electrode 20e and the first drain electrode 20f are respectively and electrically connected to the first source region 16ba and the first drain region 16bb of each first semiconductor layer 16b through respective contact holes formed in the second interlayer insulating film 19. Moreover, similar to the source line 20h and the power supply line 20i, the first source electrode 20e and the first drain electrode 20f are formed of the third metal film.

Described here is an operation of the gate driver circuit M (the flip-flop circuit A and the CMOS circuit C).

As to the flip-flop circuit A, for example, when the clock signal CK is at the low level, the inverted clock signal CKB is at the high level, and the start pulse SU is at the low level, the first peripheral TFT 9e and the third peripheral TFT 9g turn ON. Here, the start pulse SU at the low level is input to the second gate electrode 14a of the second peripheral TFT 9f, and the second peripheral TFT 9f turns ON. Whereas, the inverted clock signal CKB at the high level is applied to the second source electrode 20c of the second peripheral TFT 9f, such that the second peripheral TFT 9f does not conduct a current. Hence, a gate signal at the high level is output to the node N1. Subsequently, the gate signal at the high level output from the node N1 is input to the node N3. Because the gate signal has the same potential as the potential of the high-level voltage VDD, the fourth peripheral TFT 9h turns OFF, the fifth peripheral TFT 9i turns ON, and the gate signal having the same potential as the potential of the low-level voltage VSS is output from the node N4.

Next, as to the flip-flop circuit A, for example, when the clock signal CK is at the high level, the inverted clock signal CKB is at the low level, and the start pulse SU is at the high level, the first peripheral TFT 9e and the third peripheral TFT 9g turn OFF. Here, the inverted clock signal CKB at the low level is input to the second source electrode 20c of the second peripheral TFT 9f, and the second peripheral TFT 9f turns ON. Then, a current flows through the second peripheral TFT 9f because of the high-level voltage stored in the node N1, and the voltage of the node N1 falls by the inverted clock signal CKB at the low level. This is because the node N2 connected to one of the terminals of the capacitor 9j is in a floating state since the third peripheral TFT 9g is OFF, and thus the voltage of the node N2 falls by the fall of the voltage of the node N1, thereby enabling full-down. Hence, a gate signal at the low level is output to the node N1. Subsequently, the gate signal at the low level output from the node N1 is input to the node N3. When the gate signal has the same potential as the potential of the low-level voltage VSS, the fourth peripheral TFT 9h turns ON, the fifth peripheral TFT 9i turns OFF, and the gate signal having the same potential as the potential of the high-level voltage VDD is output from the node N4.

The above organic EL display device 50 displays an image as follows: In each of the subpixels P, a gate signal is input to the first pixel TFT 9a through the gate line 18g to turn ON the first pixel TFT 9a. Through the source line 20h, a data signal is written to the gate electrode 18a of the second pixel TFT 9b and the capacitor 9c. A current based on a gate voltage of the second pixel TFT 9b is supplied from the power supply line 20i to the organic EL layer 33, and the light-emitting layer 3 of the organic EL layer 33 emits light to display an image. Note that, in the organic EL display device 50, even if the first pixel TFT 9a turns OFF, the gate voltage of the second pixel TFT 9b is held in the capacitor 9c. Hence, the light-emitting layer 3 keeps emitting light until a gate signal in the next frame is input.

Described next will be a method for producing the organic EL display device 50 of this embodiment. Here, the method for producing the organic EL display device 50 of this embodiment includes: a TFT-layer forming step; an organic-EL-element-layer forming step; and a sealing-film forming step.

### TFT-layer Forming Step

First, a silicon nitride film (approximately 50 nm in thickness) and a silicon oxide film (approximately 250 nm in thickness) are sequentially deposited by, for example, plasma chemical vapor deposition (CVD) on the resin substrate 10 formed on a glass substrate. Hence, the base coat film 11 is formed.

Then, on a substrate surface provided with the base coat film 11, an amorphous silicon film (approximately 50 nm in thickness) is deposited by, for example, the plasma CVD. The amorphous silicon film is crystallized by such a technique as laser annealing to form a second semiconductor film formed of polysilicon. After that, the second semiconductor film is patterned to form such a layer as the second semiconductor layer 12a.

After that, on the substrate surface provided with the second semiconductor layer 12a, a silicon oxide film (approximately 100 nm in thickness) is deposited by, for example, the plasma CVD to form the first gate insulating film 13.

Furthermore, on the substrate surface provided with the first gate insulating film 13, a first metal film such as a molybdenum film (approximately 200 nm in thickness) is formed by, for example, sputtering. After that, the first metal film is patterned to form, for example, the second gate electrode 14a.

Then, using the second gate electrode 14a as a mask, the second semiconductor layer 12a is doped with impurity ions so that a portion of the second semiconductor layer 12a becomes conductive to form the second source region 12aa, the second drain region 12ab, and the second channel region 12ac in the second semiconductor layer 12a.

After that, on the substrate surface of the conductive portion in the second semiconductor layer 12a, a silicon nitride film (approximately 150 nm in thickness) and a silicon oxide film (approximately 100 nm in thickness) are sequentially deposited by, for example, the plasma CVD. Hence, the first interlayer insulating film 15 is formed.

Furthermore, on the substrate surface provided with the first interlayer insulating film 15, a first semiconductor film of an oxide semiconductor formed of such a substance as an InGaZnO₄ film (approximately 30 nm in thickness) is deposited by, for example, sputtering. After that, the first semiconductor film is patterned to form the first semiconductor layers 16a and 16b.

Subsequently, on the substrate surface provided with such a layer as the first semiconductor layer 16a, a silicon oxide film (approximately 100 nm in thickness) is deposited by, for example, the plasma CVD. After that, a second metal film such as a molybdenum film (approximately 200 nm in thickness) is deposited by, for example, sputtering. The second metal film is patterned to form such constituent features as the gate electrode 18a, the first gate electrode 18b, and the gate line 18g.

After that, the silicon oxide film exposed from the gate electrode 18a, the first gate electrode 18b, and the gate line 18g is etched to form such films as the second gate insulating films 17a and 17b.

Moreover, on the substrate surface provided with the second gate insulating films 17a and 17b, a silicon oxide film (approximately 300 nm in thickness) and a silicon nitride film (approximately 150 nm in thickness) are sequentially deposited by, for example, the plasma CVD. Hence, the second interlayer insulating film 19 is formed. Note that, by heat treatment given to the formed second interlayer insulating film 19, portions of the first semiconductor layers 16a and 16b become conductive to form: the first source region 16aa, the first drain region 16ab, and the first channel region 16ac in the first semiconductor layer 16a; and the first source region 16ba, the first drain region 16bb, and the first channel region 16bc in the first semiconductor layer 16b.

Subsequently, on the substrate surface provided with the second interlayer insulating film 19, the first gate insulating film 13, the first interlayer insulating film 15, and the second interlayer insulating film 19 are patterned as appropriate. Hence, contact holes are formed.

After that, on the substrate surface having the contact holes, a titanium film (approximately 50 nm in thickness), an aluminum film (approximately 400 nm in thickness), and a titanium film (approximately 100 nm in thickness) are sequentially deposited by, for example, sputtering to form the third metal film. After that, the third metal film is patterned to form such constituent features as the source electrode 20a, the drain electrode 20b, the second source electrode 20c, the second drain electrode 20d, the first source electrode 20e, the first drain electrode 20f, the source line 20h, and the power supply line 20i.

Furthermore, on the substrate surface provided with such an electrode as the source electrode 20a, a silicon oxide film (approximately 250 nm in thickness) is deposited by, for example, the plasma CVD to form the protective insulating film 21.

Subsequently, the substrate surface provided with the protective insulating film 21 is coated with an acrylic-based photosensitive resin film (approximately 2 μm in thickness) by, for example, spin coating or slit coating. After that, the coating film is pre-baked, exposed to light, developed, and post-baked to form the planarization film 22 having a contact hole.

Finally, the protective insulating film 21 exposed from the contact hole of the planarization film 22 is removed, so that the contact hole reaches the drain electrode 20b of the second pixel TFT 9b.

As described above, the TFT layer 30 is successfully formed.

### Organic-EL-Element Layer Forming Step

On the planarization film 22 of the TFT layer 30 formed at the TFT-layer forming step, the first electrode 31, the edge cover 32, the organic EL layer 33 (including the hole injection layer 1, the hole transport layer 2, the light-emitting layer 3, the electron transport layer 4, and the electron injection layer 5), and the second electrode 34 are formed, using a known technique. Hence, the organic-EL-element layer 40 is formed.

### Sealing-film Forming Step

First, on the substrate surface provided with the organic-EL-element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on the substrate surface provided with the first inorganic sealing film 41, an organic resin material such as acrylic resin is deposited by, for example, inkjet printing. Hence, the organic sealing film 42 is formed.

Furthermore, on the substrate provided with the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the sealing film 45 is formed.

Finally, a protective sheet (not shown) is attached to the substrate surface provided with the sealing film 45. After that, a laser beam is emitted from toward the glass substrate of the resin substrate 10, and the glass substrate is removed from a lower surface of the resin substrate 10. Moreover, a protective sheet (not shown) is attached to the lower surface of the resin substrate 10 from which the glass substrate is removed.

As can be seen, the organic EL display device 50 of this embodiment is successfully produced.

As described above, as to the organic EL display device 50 of this embodiment, the fifth peripheral TFT 9i of the CMOS circuit C includes: the plurality of first semiconductor layers 16b provided to extend in parallel with one another; the first gate electrode 18b provided to overlap with the first channel region 16bc of each of the first semiconductor layers 16b through the second gate insulating film 17b; the first source electrode 20e electrically connected to the first source region 16ba of each first semiconductor layer 16b; and the first drain electrode 20f electrically connected to the first drain region 16bb of each first semiconductor layer 16b. Thus, for example, a plurality of TFT units with a narrow channel width of approximately 10 mm are connected together in parallel with one another. Such an arrangement makes it possible to output a large current from the CMOS circuit C without increasing the channel width. Furthermore, as to the TFT units connected together in parallel with one another, each of the TFT units has a narrow channel width. Hence, a drain current is less likely to be generated in the OFF state, thereby making it possible to reduce deterioration in characteristics of the TFT units. Such a feature successfully reduces deterioration in characteristics of the fifth peripheral TFT 9i, which is an N-channel TFT, formed of an oxide semiconductor and included in the CMOS circuit provided to the output of the gate driver circuit M.

### Second Embodiment

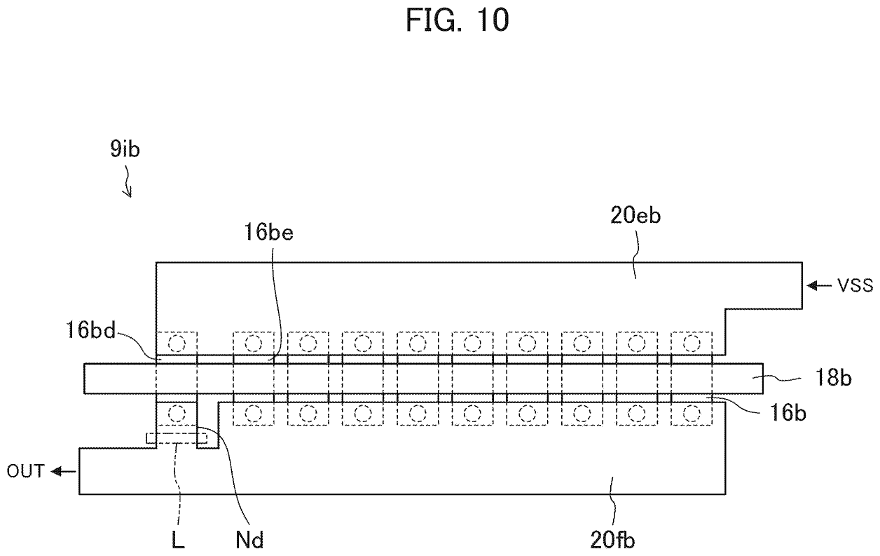

FIGS. 9 and 10 illustrate a display device according to a second embodiment of the present invention. Here, FIG. 9 is a plan view of a fifth peripheral TFT 9ia included in the CMOS circuit C of an organic EL display device according to this embodiment. Furthermore, FIG. 10 is a plan view of a fifth peripheral TFT 9ib that is a modification of the fifth peripheral TFT 9ia. For convenience in description, like reference signs designate identical constituent features throughout FIGS. 1 to 8. These constituent features will not be elaborated upon here.

The first embodiment describes, as an example, the organic EL display device 50 including the fifth peripheral TFT 9i provided with a plurality of TFT units having a narrow channel width and arranged in parallel with one another. Whereas, this embodiment describes, as an example, an organic EL display device including the fifth peripheral TFT 9ia provided not only with a plurality of TFT units having a narrow channel width and arranged in parallel with one another, but also with a wiring pattern for a repair by emission of a laser beam.

The organic EL display device of this embodiment includes the fifth peripheral TFT 9ia instead of the fifth peripheral TFT 9i. Otherwise, the organic EL display device of this embodiment is substantially the same as the organic EL display device 50 of the first embodiment. Hence, mainly described below will be a configuration of the fifth peripheral TFT 9ia.

As illustrated in FIG. 9, the fifth peripheral TFT 9ia includes: the plurality of first semiconductor layers 16b provided on the first interlayer insulating film 15 to extend in parallel with one another; the first gate electrode 18b provided above each of the first semiconductor layers 16b through the second gate insulating film 17b; and a first source electrode 20ea and a first drain electrode 20fa provided on the second interlayer insulating film 19 and spaced apart from each other. Furthermore, similar to the first embodiment described above, the fifth peripheral TFT 9ia has: a gate electrode (the first gate electrode 18b) electrically connected to the node N3; a source electrode (the first source electrode 20ea) electrically connected to a power supply line of the low-level voltage VSS; and a drain electrode (the first drain electrode 20fa) electrically connected to the node N4.

The first source electrode 20ea and the first drain electrode 20fa are respectively and electrically connected to the first source region 16ba and the first drain region 16bb of each first semiconductor layer 16b through respective contact holes formed in the second interlayer insulating film 19. Moreover, similar to the source line 20h and the power supply line 20i, the first source electrode 20ea and the first drain electrode 20fa are formed of the third metal film. Here, as illustrated in FIG. 9, the first source electrode 20ea is provided with a source notch Ns that opens toward the first gate electrode 18b between: an outermost first semiconductor layer 16bd included in the plurality of first semiconductor layers 16b and provided closest (on the left in the drawing) to the display region D; and a next outermost first semiconductor layer 16be: included in the plurality of first semiconductor layers 16b; and adjacent to the outermost first semiconductor layer 16bd. Furthermore, as illustrated in FIG. 9, the first drain electrode 20fa is provided with a drain notch Nd that opens toward the first gate electrode 18b between the outermost first semiconductor layer 16bd and the next outermost first semiconductor layer 16be. At the TFT-layer forming step described in the above first embodiment, the contact holes are formed before the third metal film is formed. Here, even if static electricity builds up along the gate line 18g during the production step and the static electricity is discharged such that a portion of the fifth peripheral TFT 9ia is broken, a portion of the first drain electrode 20fa is cut off with a laser beam emitted to a region L (see FIG. 9) near the drain notch Nd. Thanks to such a feature, one TFT unit having the outermost first semiconductor layer becomes inoperable; however, the fifth peripheral TFT 9ia can operate nearly normally.

Note that this embodiment describes, as an example, the fifth peripheral TFT 9ia in which the source notch Ns is provided to the first source electrode 20ed and the drain notch Nd is provided to the first drain electrode 20fa. Alternatively, this embodiment may provide the fifth peripheral TFT 9ib including the drain notch Nd alone provided to the first drain electrode 20fb.

Specifically, as illustrated in FIG. 10, the fifth peripheral TFT 9ib includes: the plurality of first semiconductor layers 16b provided on the first interlayer insulating film 15 to extend in parallel with one another; the first gate electrode 18b provided above each of the first semiconductor layers 16b through the second gate insulating film 17b; and a first source electrode 20eb and a first drain electrode 20fb provided on the second interlayer insulating film 19 and spaced apart from each other. Furthermore, similar to the first embodiment described above, the fifth peripheral TFT 9ia has: a gate electrode (the first gate electrode 18b) electrically connected to the node N3; a source electrode (the first source electrode 20eb) electrically connected to a power supply line of the low-level voltage VSS; and a drain electrode (the first drain electrode 20fb) electrically connected to the node N4.

The first source electrode 20eb and the first drain electrode 20fb are respectively and electrically connected to the first source region 16ba and the first drain region 16bb of each first semiconductor layer 16b through respective contact holes formed in the second interlayer insulating film 19. Moreover, similar to the source line 20h and the power supply line 20i, the first source electrode 20eb and the first drain electrode 20fb are formed of the third metal film. Here, as illustrated in FIG. 10, the first drain electrode 20fb is provided with the drain notch Nd that opens toward the first gate electrode 18b between the outermost first semiconductor layer 16bd and the next outermost first semiconductor layer 16be.

Similar to the organic EL display device 50 of the first embodiment, the organic EL display device of this embodiment is flexible. The organic EL display device of this embodiment displays an image when, in each of the subpixels P, the light-emitting layer 3 of the organic EL layer 33 emits light as appropriate through the first pixel TFT 9a and the second pixel TFT 9b.

The organic EL display device of this embodiment can be produced by the method for producing the organic EL display device 50 of the first embodiment. At the TFT-layer forming step, the first source electrode 20e and the first drain electrode 20f are patterned into a different shape.

As described above, as to the organic EL display device of this embodiment, the fifth peripheral TFT 9ia of the CMOS circuit C includes: the plurality of first semiconductor layers 16b provided to extend in parallel with one another; the first gate electrode 18b provided to overlap with the first channel region 16bc of each of the first semiconductor layers 16b through the second gate insulating film 17b; the first source electrode 20ea electrically connected to the first source region 16ba of each first semiconductor layer 16b; and the first drain electrode 20fa electrically connected to the first drain region 16bb of each first semiconductor layer 16b. Thus, for example, a plurality of TFT units with a narrow channel width of approximately 10 mm are connected together in parallel with one another. Such an arrangement makes it possible to output a large current from the CMOS circuit C without increasing the channel width. Furthermore, as to the TFT units connected together in parallel with one another, each of the TFT units has a narrow channel width. Hence, a drain current is less likely to be generated in the OFF state, thereby making it possible to reduce deterioration in characteristics of the TFT units. Such a feature successfully reduces deterioration in characteristics of the fifth peripheral TFT 9ia, which is an N-channel TFT, formed of an oxide semiconductor and included in the CMOS circuit provided to the output of the gate driver circuit M.

Moreover, as to the organic EL display device of this embodiment, the first drain electrode 20fa is provided with the drain notch Nd that opens toward the first gate electrode 18b between the outermost first semiconductor layer 16bd and the next outermost first semiconductor layer 16be, and first source electrode 20ea is provided with the source notch Ns that opens toward the first gate electrode 18b between the outermost first semiconductor layer 16bd and the next outermost first semiconductor layer 16be. Hence, even if static electricity builds up along the gate line 18g during the production step and the static electricity is discharged such that a portion of the fifth peripheral TFT 9ia is broken, a portion of the first drain electrode 20fa and/or a portion of the first source electrode 20ea are/is cut off with a laser beam emitted near the source notch Ns and/or the drain notch Nd. Thanks to such a feature, the fifth peripheral TFT 9ia can operate nearly normally.

### Third Embodiment

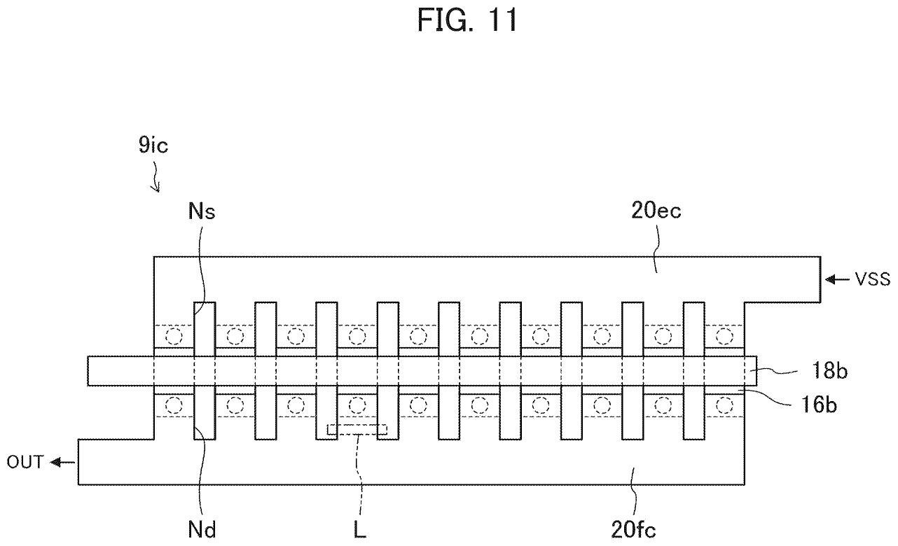

FIG. 11 illustrates a display device according to a third embodiment of the present invention. Here, FIG. 11 is a plan view of a fifth peripheral TFT 9ic included in the CMOS circuit C of an organic EL display device according to this embodiment.

The second embodiment describes, as an example, the organic EL display device including the fifth peripheral TFT 9ia having a wiring pattern for repairing an element malfunctioning because of discharge of static electricity. This embodiment describes, as an example, an organic EL display device including the fifth peripheral TFT 9ic having a wiring pattern for repairing an element malfunctioning because of discharge of static electricity and of mixture of a foreign substance.

The organic EL display device of this embodiment includes the fifth peripheral TFT 9ic instead of the fifth peripheral TFT 9i. Otherwise, the organic EL display device of this embodiment is substantially the same as the organic EL display device 50 of the first embodiment. Hence, mainly described below will be a configuration of the fifth peripheral TFT 9ic.

Specifically, as illustrated in FIG. 11, the fifth peripheral TFT 9ic includes: the plurality of first semiconductor layers 16b provided on the first interlayer insulating film 15 to extend in parallel with one another; the first gate electrode 18b provided above each of the first semiconductor layers 16b through the second gate insulating film 17b; and a first source electrode 20ec and a first drain electrode 20fc provided on the second interlayer insulating film 19 and spaced apart from each other. Furthermore, similar to the first embodiment described above, the fifth peripheral TFT 9ic has: a gate electrode (the first gate electrode 18b) electrically connected to the node N3; a source electrode (the first source electrode 20ec) electrically connected to a power supply line of the low-level voltage VSS; and a drain electrode (the first drain electrode 20fc) electrically connected to the node N4.

The first source electrode 20ec and the first drain electrode 20fc are respectively and electrically connected to the first source region 16ba and the first drain region 16bb of each first semiconductor layer 16b through respective contact holes formed in the second interlayer insulating film 19. Moreover, similar to the source line 20h and the power supply line 20i, the first source electrode 20ec and the first drain electrode 20fc are formed of the third metal film. Here, as illustrated in FIG. 11, the first source electrode 20ec is provided with a plurality of the source notches Ns that open toward the first gate electrode 18b between the plurality of first semiconductor layers 16b. Furthermore, as illustrated in FIG. 11, the first drain electrode 20fc is provided with a plurality of the drain notches Nd that open toward the first gate electrode 18b between the plurality of first semiconductor layers 16b. At the TFT-layer forming step described in the first embodiment, the contact holes are formed before the third metal film is formed. Here, even if static electricity builds up along the gate line 18g during the production step and the static electricity is discharged such that a portion of the fifth peripheral TFT 9ic is broken, a portion of the first source electrode 20ec and/or a portion of the first drain electrode 20fc are/is cut off with a laser beam emitted near the source notch Ns and/or the drain notch Nd closest to the display region D. Thanks to such a feature, the fifth peripheral TFT 9ic can operate nearly normally. Furthermore, even if a foreign substance is mixed during the production step such that a portion of the fifth peripheral TFT 9ic is broken, a portion of the first source electrode 20ec and/or a portion of the first drain electrode 20fc are/is cut off with a laser beam emitted to the region L (see FIG. 9) near a source notch Ns and/or a drain notch Nd affected by the foreign substance. Thanks to such a feature, the fifth peripheral TFT 9ic can operate nearly normally.

Similar to the organic EL display device 50 of the first embodiment, the organic EL display device of this embodiment is flexible. The organic EL display device of this embodiment displays an image when, in each of the subpixels P, the light-emitting layer 3 of the organic EL layer 33 emits light as appropriate through the first pixel TFT 9a and the second pixel TFT 9b.

The organic EL display device of this embodiment can be produced by the method for producing the organic EL display device 50 of the first embodiment. At the TFT-layer forming step, the first source electrode 20e and the first drain electrode 20f are patterned into a different shape.

As described above, as to the organic EL display device of this embodiment, the fifth peripheral TFT 9ic of the CMOS circuit C includes: the plurality of first semiconductor layers 16b provided to extend in parallel with one another; the first gate electrode 18b provided to overlap with the first channel region 16bc of each of the first semiconductor layers 16b through the second gate insulating film 17b; the first source electrode 20ec electrically connected to the first source region 16ba of each first semiconductor layer 16b; and the first drain electrode 20fc electrically connected to the first drain region 16bb of each first semiconductor layer 16b. Thus, for example, a plurality of TFT units with a narrow channel width of approximately 10 mm are connected together in parallel with one another. Such an arrangement makes it possible to output a large current from the CMOS circuit C without increasing the channel width. Furthermore, as to the TFT units connected together in parallel with one another, each of the TFT units has a narrow channel width. Hence, a drain current is less likely to be generated in the OFF state, thereby making it possible to reduce deterioration in characteristics of the TFT units. Such a feature successfully reduces deterioration in characteristics of the fifth peripheral TFT 9ic, which is an N-channel TFT, formed of an oxide semiconductor and included in the CMOS circuit provided to the output of the gate driver circuit M.

Moreover, as to the organic EL display device of this embodiment, the first drain electrode 20fc is provided with the plurality of drain notches Nd that open toward the first gate electrode 18b between the plurality of first semiconductor layers 16b, and first source electrode 20ec is provided with the source notches Ns that open toward the first gate electrode 18b between the plurality of the first semiconductor layers 16b. Hence, even if static electricity builds up along the gate line 18g during the production step and the static electricity is discharged such that a portion of the fifth peripheral TFT 9ic is broken, a portion of the first drain electrode 20fc and/or a portion of the first source electrode 20ec are/is cut off with a laser beam emitted near a source notch Ns and/or a drain notch Nd toward the display region D. Thanks to such a feature, the fifth peripheral TFT 9ic can operate nearly normally. Furthermore, even if a foreign substance is mixed during the production step such that a portion of the fifth peripheral TFT 9ic is broken, a portion of the first source electrode 20ec and/or a portion of the first drain electrode 20fc are/is cut off with a laser beam emitted near a source notch Ns and/or a drain notch Nd affected by the foreign substance. Thanks to such a feature, the fifth peripheral TFT 9ic can operate nearly normally.

### Other Embodiments

Each of the above embodiments exemplifies a case where the fifth peripheral TFT is an N-channel TFT formed of an oxide semiconductor, and is provided with a plurality of TFT units having a narrow channel width and arranged in parallel with one another. However, each embodiment may exemplify a case where the fourth peripheral TFT is a P-channel TFT formed of polysilicon, and is provided with: a plurality of TFT units having a narrow channel width, and arranged in parallel with one another; and a wiring pattern for a repair by emission of a laser beam.

Each of the above embodiments exemplifies an organic EL display device including a resin substrate serving as a base substrate. Alternatively, the present invention is also applicable to display devices such as an organic EL display device and a liquid crystal display device including a glass substrate serving as a base substrate.

In each of the above embodiments, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in each of the above embodiments, the exemplified organic EL display device includes a first electrode as an anode and a second electrode as a cathode. The present invention can also be applied to an organic EL display device whose multilayer structure of the organic EL layer is inverted, and the first electrode is a cathode and the second electrode is an anode.

Furthermore, in each of the above embodiments, the exemplified organic EL display device in which an electrode of a TFT connected to a first electrode is a drain electrode. The present invention can also be applied to an organic EL display device in which an electrode of a TFT connected to a first electrode is referred to as a source electrode.

In addition, in each of the embodiments, the organic EL display device is exemplified as a display device. The present invention can be applied to a display device including a plurality of light-emitting elements driven by currents. For example, the present invention can be applied to a display device including quantum-dot light-emitting diodes (QLEDs); that is, light-emitting elements including layers containing quantum dots.

### INDUSTRIAL APPLICABILITY

As described above, the present invention is useful for a flexible display device.

### REFERENCE SIGNS LIST

C CMOS Circuit (Complementary Metal Oxide Semiconductor Circuit)
D Display Region
F Picture-Frame Region
M Gate Driver Circuit (Drive Circuit)
Nd Drain Notch
Ns Source Notch
P Subpixel
9a First Pixel TFT (Pixel Thin-Film Transistor, First Thin-Film Transistor)
9b Second Pixel TFT (Pixel Thin-Film Transistor, First Thin-Film Transistor)
9e First Peripheral TFT (Second Thin-Film Transistor)
9f Second Peripheral TFT (Second Thin-Film Transistor)
9g Third Peripheral TFT (Second Thin-Film Transistor)
9h Fourth Peripheral TFT (Second Thin-Film Transistor)
9i Fifth Peripheral TFT (First Thin-Film Transistor)
10 Resin Substrate (Base Substrate)
12a Second Semiconductor Layer
12aa Second Source Region
12ab Second Drain Region
12ac Second Channel Region
13 First Gate Insulating Film (Second Inorganic Insulating Film)
14a Second Gate Electrode
15 First Interlayer Insulating Film (Third Inorganic Insulating Film)
16b First Semiconductor Layer
16ba First Source Region
16bb First Drain Region
16bc First Channel Region
16bd Outermost First Semiconductor Layer
16be Next Outermost First Semiconductor Layer
17a and 17b Second Gate Insulating Film (First Inorganic Insulating Film)
18b First Gate Electrode
19 Second Interlayer Insulating Film (Fourth Inorganic Insulating Film)
20c Second Source Electrode
20d Second Drain Electrode
20e, 20ea, and 20ec First Source Electrode
20f, 20fa, and 20fc First Drain Electrode
30 TFT Layer (Thin-Film Transistor Layer)
35 Organic EL Element (Organic Electroluminescence Element, Light-Emitting Element)
40 Organic-EL-Element Layer (Light-Emitting Element Layer)
45 Sealing Film
50 Organic EL Display Device

1. A display device, comprising:
a base substrate;
a thin-film transistor layer provided on the base substrate and including a first thin-film transistor and a second thin-film transistor, the first thin-film transistor having a first semiconductor layer formed of an oxide semiconductor and including a first channel region, a first source region, and a first drain region, and the second thin-film transistor having a second semiconductor layer formed of polysilicon;
a display region configured to display an image, and a picture-frame region defined around the display region; and
a complementary metal oxide semiconductor circuit included in the picture-frame region and provided to an output of a drive circuit so as to serve as a portion of the drive circuit, the complementary metal oxide semiconductor circuit being a combination of the first thin-film transistor and the second thin-film transistor,
wherein the first thin-film transistor of the complementary metal oxide semiconductor circuit includes: a plurality of the first semiconductor layers provided to extend in parallel with one another; a first gate electrode provided to overlap with the first channel region of each of the first semiconductor layers through a first inorganic insulating film; a first source electrode electrically connected to the first source region of each first semiconductor layer; and a first drain electrode electrically connected to the first drain region of each first semiconductor layer.

2. The display device according to claim 1,
wherein the first drain electrode is provided with a drain notch that opens toward the first gate electrode between: an outermost first semiconductor layer included in the plurality of first semiconductor layers and provided closest to the display region; and a next outermost first semiconductor layer included in the plurality of first semiconductor layers and adjacent to the outermost first semiconductor layer.

3. The display device according to claim 2,
wherein the first source electrode is provided with a source notch that opens toward the first gate electrode between the outermost first semiconductor layer and the next outermost first semiconductor layer.

4. The display device according to claim 1,
wherein the first drain electrode is provided with a plurality of drain notches that open toward the first gate electrode between the plurality of first semiconductor layers.

5. The display device according to claim 4,
wherein the first source electrode is provided with a plurality of source notch that open toward the first gate electrode between the plurality of first semiconductor layers.

6. The display device according to 5claim 1,
wherein the thin-film transistor layer includes: a second semiconductor film formed of polysilicon; a second inorganic insulating film; a first metal film; a third inorganic insulating film; a first semiconductor film formed of an oxide semiconductor; the first inorganic insulating film; a second metal film; a fourth inorganic insulating film; and a third metal film, all of which are sequentially stacked on top of another,
the first semiconductor layer is formed of the first semiconductor film,
the second semiconductor layer is formed of the second semiconductor film,
the first gate electrode is formed of the second metal film, and
the first source electrode and the first drain electrode are formed of the third metal film.

7. The display device according to claim 6,
wherein the second thin-film transistor of the complementary metal oxide semiconductor circuit includes: the second semiconductor layer having a second channel region, a second source region, and a second drain region; a second gate electrode formed of the first metal film and provided to overlap with the second channel region of the second semiconductor layer through the second inorganic insulating film; a second source electrode formed of the third metal film and electrically connected to the second source region of the second semiconductor layer; and a second drain electrode formed of the third metal film and electrically connected to the second drain region of the second semiconductor layer.

8. The display device according to claim 1,
wherein the display region includes a plurality of subpixels each provided with a plurality of pixel thin-film transistors serving as the first thin-film transistor.

9. The display device according to claim 1, further comprising:
a light-emitting-element layer provided on the thin-film transistor layer and including a plurality of light-emitting elements arranged to correspond to the plurality of subpixels included in the display region; and
a sealing film provided on the light-emitting-element layer.

10. The display device according to claim 9,
wherein each of the light-emitting elements is an organic electroluminescence element.
